(19) United States
(12) Patent Application Publication
(10) Pub. No.: US 2024/0130115 A1
(43) Pub. Date: Apr. 18, 2024

(54) INTEGRATED CIRCUIT DEVICE AND METHOD OF MANUFACTURING THE SAME

(71) Applicant: Samsung Electronics Co., Ltd., Suwon-si (KR)

(72) Inventor: Hoju Song, Suwon-si (KR)

(73) Assignee: Samsung Electronics Co., Ltd., Suwon-si (KR)

(21) Appl. No.: 18/367,183

(22) Filed: Sep. 12, 2023

(30) Foreign Application Priority Data
Oct. 14, 2022 (KR) 10-2022-0132718

(51) Int. Cl. H10B 12/00

(52) U.S. Cl. CPC H10B 12/482; H10B 12/02; H10B 12/315; H10B 12/36

(57) ABSTRACT

An integrated circuit (IC) device is provided. The IC device includes: a substrate having active regions; word lines extending in a first horizontal direction across the active regions; conductive expanded pads on the substrate and connected to the active regions; pad isolation structures located between the conductive expanded pads; direct contacts connected to the active regions; bit lines extending in a second horizontal direction perpendicular to the first horizontal direction, on the direct contacts and the pad isolation structures, and connected to the direct contacts; conductive plugs extending in a vertical direction on the conductive expanded pads and connected to the conductive expanded pads; and separation fences passing through the conductive expanded pads and the conductive plugs, and having sidewalls extending linearly in the vertical direction.

### CROSS-REFERENCE TO RELATED APPLICATION

This application claims priority to Korean Patent Application No. 10-2022-0132718, filed on Oct. 14, 2022, in the Korean Intellectual Property Office, the disclosure of which is incorporated herein by reference in its entirety.

### BACKGROUND

The present disclosure relates to an integrated circuit (IC) device, and more particularly, to an IC device having a buried word line and a method of manufacturing the same.

As IC elements are increasingly integrated, the pitch of conductive lines decreases. A technique is needed to ensure a reliable electrical connection between adjacent conductive regions.

### SUMMARY

The present disclosure provides an integrated circuit (IC) device having a structure capable of securing reliable electrical connection between adjacent conductive regions in a device region having an area reduced due to downscaling.

The present disclosure provides a method of manufacturing an IC device having a structure capable of securing reliable electrical connection between adjacent conductive regions in a device region having an area reduced according to downscaling.

According to an aspect of an embodiment, an IC device includes: a substrate having a plurality of active regions; a plurality of word lines extending in a first horizontal direction across the plurality of active regions; a plurality of bit lines extending on the substrate in a second horizontal direction perpendicular to the first horizontal direction; a plurality of conductive vertical structures including a plurality of conductive expanded pads and a plurality of conductive contact plugs, wherein the plurality of conductive expanded pads are closer to a bottom surface of the substrate than the plurality of bit lines and are in contact with the plurality of active regions, and the plurality of conductive contact plugs extend in a vertical direction and are connected to the plurality of conductive expanded pads between each of the plurality of bit lines; and a plurality of separation fences separating the plurality of conductive vertical structures from each other, between each of the plurality of bit lines, and having sidewalls extending linearly in contact with the plurality of conductive vertical structures.

According to another aspect of an embodiment, an IC device includes: a substrate having a plurality of active regions; a plurality of word lines extending in a first horizontal direction across the plurality of active regions; a plurality of conductive expanded pads on the substrate and connected to the plurality of active regions; a plurality of pad isolation structures located between the plurality of conductive expanded pads; a plurality of direct contacts connected to the plurality of active regions; a plurality of bit lines extending in a second horizontal direction perpendicular to the first horizontal direction, on the plurality of direct contacts and the plurality of pad isolation structures, and connected to the plurality of direct contacts; a plurality of conductive plugs extending in a vertical direction on the plurality of conductive expanded pads and connected to the plurality of conductive expanded pads; and a plurality of separation fences passing through the plurality of conductive expanded pads and the plurality of conductive plugs, and having sidewalls extending linearly in the vertical direction.

According to another aspect of an embodiment, an IC device includes: a substrate having a plurality of active regions spaced apart from each other; a plurality of word lines extending in a first horizontal direction across the plurality of active regions; a plurality of bit line structures spaced apart from each other in the first horizontal direction on the substrate and including a plurality of bit lines and a plurality of spacer structures, wherein the plurality of bit lines extend in a second horizontal direction intersecting the first horizontal direction, and the plurality of spacer structures are provided on both sidewalls of the plurality of bit lines; a plurality of direct contacts connecting the plurality of active regions to the plurality of bit lines; a plurality of pad isolation structures spaced apart from each other in the second horizontal direction with the plurality of direct contacts therebetween, wherein the plurality of pad isolation structures are between the a lower surface of the substrate and the plurality of bit line structures; a plurality of conductive vertical structures including a plurality of conductive expanded pads and a plurality of conductive contact plugs, wherein the plurality of conductive expanded pads are spaced apart from each other in the first horizontal direction with the plurality of pad isolation structures therebetween, and the plurality of conductive contact plugs are in contact with the plurality of conductive expanded pads and extend in a vertical direction; and a plurality of separation fences arranged in the second horizontal direction, between the plurality of conductive vertical structures, and having side surfaces extending linearly adjacent an interface between the plurality of conductive expanded pads and the plurality of conductive contact plugs.

### BRIEF DESCRIPTION OF DRAWINGS

The above and other aspects and features will be more apparent from the following description of embodiments, taken in conjunction with the accompanying drawings in which:

FIG. 1 is a schematic plan layout view illustrating some components of a memory cell array region of an integrated circuit (IC) device according to embodiments;

FIGS. 2A and 2B are diagrams illustrating an IC device according to embodiments, in which FIG. 2A shows cross-sectional views of some components, taken along lines X1-X1′ and X2-X2′ of FIG. 1, and FIG. 2B shows cross-sectional views of some components, taken along lines Y1-Y1′ and Y2-Y2′ of FIG. 1;

FIG. 3 is an enlarged view of portion “EX1” in FIG. 2B;

FIGS. 4A and 4B are enlarged views of a portion of an IC device of the related art, corresponding to portion “EX1” in FIG. 2B;

FIGS. 5A and 5B are diagrams illustrating an IC device according to some other embodiments, in which FIG. 5A is a cross-sectional view of some components, taken along lines X1-X1′ and X2-X2′ of FIG. 1, and FIG. 5B is a cross-sectional view of some components, taken along lines Y1-Y1′ and Y2-Y2′ of FIG. 1; and

FIGS. 6, 7A, 7B, 8, 9A, 9B, 10A, 10B, 11A, 11B, 12A, 12B, 13, 14A, 14B, 15, 16A and 16B are diagrams illustrating sequential processes of a method of manufacturing an IC device according to embodiments, in which FIGS. 6, 8, 13, and 15 are schematic plan layout views illustrating some components of a memory cell array region of an IC device, FIGS. 7A, 9A, 10A, 11A, 12A, 14A, and 16A are cross-sectional views of some components, taken along lines X1-X1′ and X2-X2′ of FIG. 1, and FIGS. 7B, 9B, 10B, 11B, 12B, 14B, and 16B are cross-sectional views of some components, taken along lines Y1-Y1′ and Y2-Y2′ of FIG. 1.

### DETAILED DESCRIPTION

Hereinafter, embodiments are described in detail with reference to the accompanying drawings. The same reference numerals are used for the same components in the drawings, and redundant descriptions thereof are omitted. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation. In the following detailed description and claims, it will be understood that, although the terms first, second, etc. may be used herein to describe various elements, these elements should not be limited by these terms. These terms are only used to distinguish one element from another.

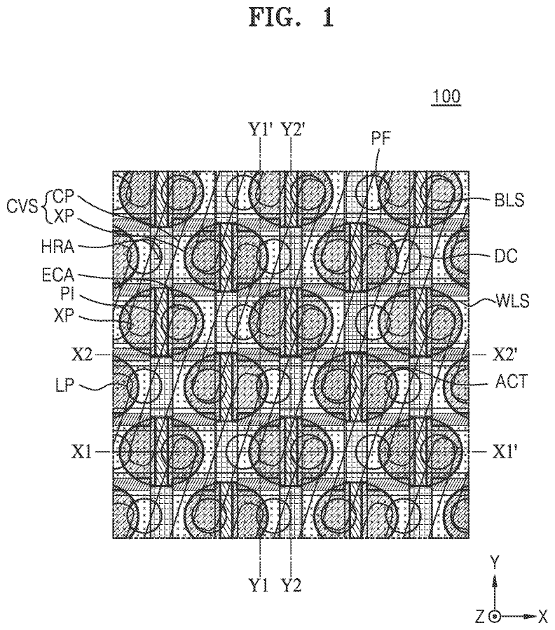

FIG. 1 is a schematic plan layout view illustrating some components of a memory cell array region of an integrated circuit (IC) device 100 according to embodiments.

Referring to FIG. 1, the IC device 100 may include a plurality of active regions ACT arranged to extend horizontally in an oblique direction with respect to a first horizontal direction (an X direction) and a second horizontal direction (a Y direction) orthogonal to each other on a plane.

According to embodiments, a plurality of word line structures WLS may extend to be parallel to each other in the first horizontal direction (the X direction) across the active regions ACT. A plurality of bit line structures BLS may extend to be parallel to each other in the second horizontal direction (the Y direction) on the word line structures WLS.

According to embodiments, the IC device 100 may include a plurality of embossed cell regions ECA including a portion of each of two adjacent active regions ACT, among the active regions ACT in a plan view. According to embodiments, the IC device 100 may include a plurality of direct contacts DC arranged below the bit line structures BLS in an engraved recess space HRA outside the embossed cell regions ECA. Each of the bit line structures BLS may be connected to the active region ACT through the direct contact DC.

According to embodiments, a plurality of conductive expanded pads XP and a plurality of pad isolation structures PI may be located in the embossed cell regions ECA. According to embodiments, the pad isolation structures PI may be located below the bit line structure BLS and may overlap the bit line structure BLS in a vertical direction (a Z direction). According to embodiments, the conductive expanded pads XP may be spaced apart from each other with the pad isolation structures PI therebetween in the first horizontal direction (the X direction).

According to embodiments, a plurality of conductive contact plugs CP may be disposed on the conductive expanded pads XP. According to embodiments, each of the conductive contact plugs CP may be located such that at least a portion thereof overlaps each of the conductive expanded pads XP in the vertical direction (the Z direction).

According to embodiments, a conductive vertical structure CVS including a conductive expanded pad XP and a conductive contact plug CP on the conductive expanded pad XP may be defined. According to embodiments, the conductive vertical structures CVS may be arranged in the second horizontal direction (the Y direction) and may be spaced apart from each other with a plurality of separation fences PF therebetween in the second horizontal direction (the Y direction).

According to embodiments, a plurality of conductive landing pads LP may be disposed on the conductive contact plugs CP. Each of the conductive landing pads LP may be located to overlap the conductive contact plug CP at least partially in the vertical direction (the Z direction). For example, a plurality of capacitor structures may be arranged on the conductive landing pads LP, and the capacitor structures may be connected to the active regions ACT through the conductive land pads LP, the conductive contact plugs CP, and the conductive expanded pads XP.

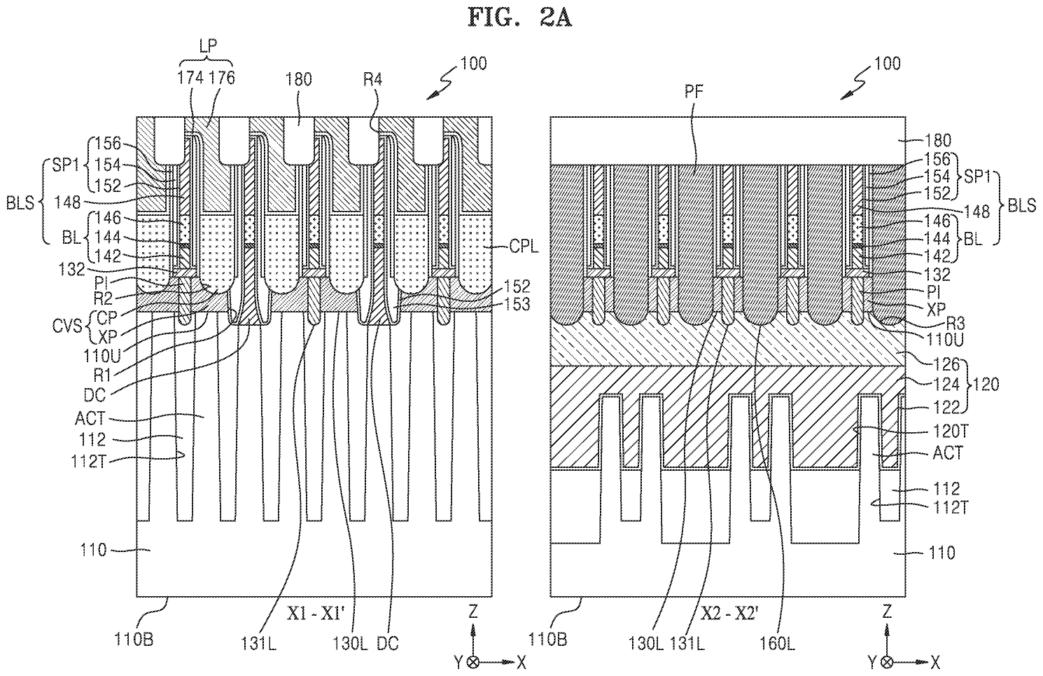

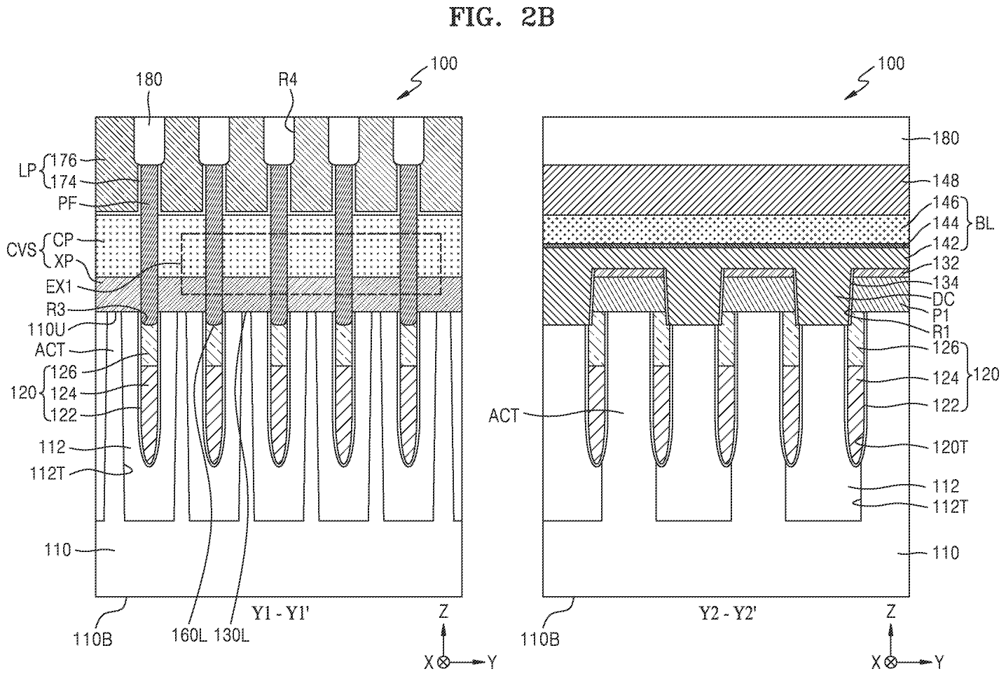

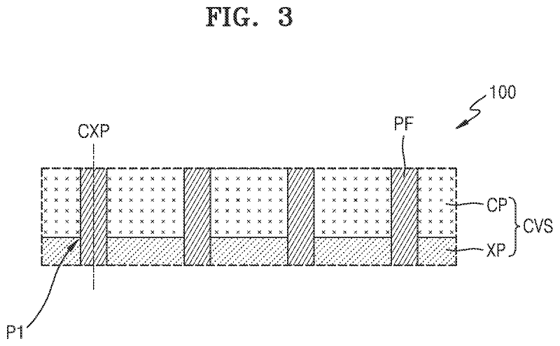

FIGS. 2A and 2B are diagrams illustrating the IC device 100 according to embodiments, in which FIG. 2A is cross-sectional views of some components, taken along lines X1-X1′ and X2-X2′ of FIG. 1 and FIG. 2B is cross-sectional views of some components, taken along lines Y1-Y1′ and Y2-Y2′ of FIG. 1. FIG. 3 is an enlarged view of portion “EX1” in FIG. 2B.

Referring to FIGS. 2A, 2B, and 3, the IC device 100 may include a substrate 110 in which the active regions ACT are defined by a device isolation trench 112T. The substrate 110 may have an upper surface 110U and a bottom surface 110B opposite to the upper surface 110U. The active regions ACT may be spaced apart from each other in a horizontal direction (e.g., the X direction and/or the Y direction). According to embodiments, the device isolation trench 112T may be filled with the device isolation layer 112. The device isolation layer 112 may surround the active regions ACT on the substrate 110.

According to embodiments, a level of a bottom of the device isolation trench 112T may vary according to a width of the device isolation trench 112T in the horizontal direction (the X direction and/or Y direction). As the width of the device isolation trench 112T in the horizontal direction (the X direction and/or Y direction) increases, the vertical level of the bottom of the device isolation trench 112T may be lower. The term “vertical level” used herein may refer to a height from the upper surface 110U of the substrate 110 in the vertical direction (the Z direction or a −Z direction).

According to embodiments, the substrate 110 may include silicon, for example, monocrystalline silicon, polycrystalline silicon, or amorphous silicon. According to other embodiments, the substrate 110 may include at least one selected from Ge, SiGe, SiC, GaAs, InAs, and InP. Terms, such as “SiGe”, “SiC”, “GaAs”, “InAs”, and “InP” used in this specification refer to materials including elements included in each term, not a chemical formula representing stoichiometric relationships, and this may be similarly understood for the terms described below. According to embodiments, the substrate 110 may include a conductive region, for example, a well doped with a dopant or a structure doped with a dopant. According to embodiments, the device isolation layer 112 may include a silicon oxide layer, a silicon nitride layer, or combinations thereof.

According to embodiments, a plurality of word line trenches 120T extending in a first horizontal direction (the X direction) may be formed in the substrate 110, and a plurality of word line structures 120 may be arranged in the word line trenches 120T. For example, the word line structures 120 may be buried in the substrate 110. According to embodiments, each of the word line structures 120 may include a gate dielectric layer 122, a word line 124, and a buried insulating layer 126. According to embodiments, the word line 124 may be disposed at a vertical level lower than the upper surface 110U of the substrate 110, and the buried insulating layer 126 may be formed within the word line trench 120T. The word line 124 may be covered by the buried insulating layer 126. According to embodiments, the gate dielectric layer 122 may conformally cover an inner surface of the word line trench 120T and may surround the word line 124 and the buried insulating layer 126. For example, the word line structure 120 may correspond to the word line structure WLS illustrated in FIG. 1.

Referring to FIGS. 1, 2A, and 2B together, the conductive expanded pads XP and the pad isolation structures PI may be disposed on the substrate 110. According to embodiments, each of the conductive expanded pads XP may contact one selected from among the active regions ACT. According to embodiments, the pad isolation structures PI may be located between two conductive expanded pads XP that are in contact with different active regions ACT and adjacent to each other.

According to embodiments, lower surfaces 131L of the pad isolation structures PI may have a vertical level lower than that of lower surfaces 130L of the conductive expanded pads XP. For example, the pad isolation structures PI may pass through an upper surface 110U of the substrate 110.

According to embodiments, the conductive contact plugs CP may include a semiconductor material doped with impurities, a metal, a conductive metal nitride, or combinations thereof. For example, the conductive expanded pads XP may include at least one of a metal, such as ruthenium (Ru), titanium (Ti), tantalum (Ta), niobium (Nb), iridium (Ir), molybdenum (Mo), or tungsten (W), a conductive metal nitride, such as titanium nitride (TiN), tantalum nitride (TaN), niobium nitride (NbN), molybdenum nitride (MoN), and tungsten nitride (WN). For example, the conductive expanded pads XP may include a doped polysilicon layer, an epitaxially grown silicon layer, or combinations thereof. According to embodiments, the pad isolation structures PI may include an oxide layer, a nitride layer, or combinations thereof.

According to embodiments, an interlayer insulating layer 132 may be disposed on the conductive expanded pads XP and the pad isolation structures PI. According to embodiments, the interlayer insulating layer 132 may include silicon oxide or silicon nitride, and may include a single layer or multiple layers. For example, the interlayer insulating layer 132 may include a silicon oxide layer or a silicon nitride layer sequentially formed on the conductive expanded pads XP and the pad isolation structures PI, but is not limited thereto.

According to embodiments, the interlayer insulating layer 132 may cover the pad isolation structures PI and may cover a portion of the conductive expanded pads XP. In some embodiments, the conductive expanded pad XP may include a portion overlapping the interlayer insulating layer 132 in the vertical direction (the Z direction) and a portion not overlapping the interlayer insulating layer 132 in the vertical direction (the Z direction). In some other embodiments, the interlayer insulating layer 132 may not cover the conductive expanded pad XP.

According to embodiments, a first recess space R1 may be provided in a partial region of the substrate 110. According to embodiments, the first recess space R1 may pass through the upper surface 110U of the substrate 110, and a lower surface of the first recess space R1 may be located at vertical level lower than that of the upper surface 110U of the substrate 110. According to embodiments, the embossed cell region ECA and the engraved recess space HRA may be defined by the first recess space R1 in the substrate 110 in a plan view. For example, in the engraved recess space HRA, a portion of the active region ACT of the substrate 110 may be exposed by the first recess space R1. For example, the conductive expanded pads XP and the pad isolation structures PI on the substrate 110 may constitute a portion protruding from the lower surface of the first recess space R1 in the embossed cell region ECA.

According to embodiments, the conductive expanded pads XP and the pad isolation structures PI may be located in the embossed cell region ECA. According to embodiments, in the embossed cell region ECA, the conductive expanded pads XP may be spaced apart from each other in the first horizontal direction (the X direction) with the pad isolation structures PI therebetween.

According to embodiments, a plurality of bit lines BL may extend to be parallel to each other in the second horizontal direction (the Y direction), while crossing the embossed cell region ECA and the engrave recess space HRA on the substrate 110. According to embodiments, the bit lines BL may be spaced apart from each other in the first horizontal direction (the X direction). According to embodiments, the bit lines BL may be disposed on the interlayer insulating layer 132 in the embossed cell region ECA, and may be disposed on partial regions of the active regions ACT, respectively, in the embossed recess space HRA. In this case, in the embossed cell region ECA, the bit lines BL may overlap the pad isolation structure PI with the interlayer insulating layer 132 therebetween in the vertical direction (the Z direction).

According to embodiments, the direct contacts DC may be disposed on portions of the active regions ACT, respectively, in the engraved recess space HRA, and the bit lines BL may be connected to the active region ACT respectively through the direct contact DC. According to embodiments, the direct contact DC may include Si, Ge, W, WN, Co, Ni, Al, Mo, Ru, Ti, TiN, Ta, TaN, Cu, or combinations thereof. According to embodiments, the direct contact DC may include a doped polysilicon layer, an epitaxially grown silicon layer, or combinations thereof.

According to embodiments, each of the bit lines BL may include a lower conductive line 142, an intermediate conductive line 144, and an upper conductive line 146 sequentially stacked on the substrate 110. According to embodiments, each of the bit lines BL may be covered by an insulating capping pattern 148. For example, the insulating capping pattern 148 may be disposed on the upper conductive line 146 in the vertical direction (the Z direction). For example, in the engraved recess space HRA, an upper surface of the lower conductive line 142 of the bit line BL may be coplanar with an upper surface of the direct contact DC.

According to embodiments, in a plan view, the pad isolation structures PI may be spaced apart from each other in the second horizontal direction (the Y direction) with the direct contacts DC therebetween below the bit line BL.

According to embodiments, in a plan view, the direct contacts DC and the pad isolation structures PI may be staggered with respect to each other below the bit line BL. For example, the direct contacts DC and the pad isolation structures PI may be alternately arranged in the second horizontal direction (the Y direction) below one bit line BL. For example, the direct contacts DC and the pad isolation structures PI may be alternately arranged in the first horizontal direction (the X direction) below the bit lines BL.

In FIGS. 2A and 2B, the bit lines BL are illustrated as having a triple conductive layer structure including the lower conductive line 142, the intermediate conductive line 144, and the upper conductive line 146, but embodiments are not limited thereto. For example, the bit lines BL may be formed as a single conductive layer, double conductive layers, or quadruple or more conductive layers.

According to embodiments, the lower conductive line 142 may include a doped polysilicon layer. The intermediate conductive line 144 and the upper conductive line 146 may include a layer including Ti, TiN, TiSiN, tungsten (W), WN, tungsten silicide (WSix), tungsten silicon nitride (WSixNy), ruthenium (Ru), or combinations thereof. For example, the intermediate conductive line 144 may include a TiN layer and/or a TiSiN layer, and the upper conductive line 146 may include a layer including Ti, TiN, W, WN, WSixNy, Ru, or combinations thereof. The insulating capping pattern 148 may include a silicon nitride layer.

Referring to FIGS. 2A and 2B, the first recess space R1 may be filled with the direct contact DC, a first inner insulating spacer 134, a second inner insulating spacer 152, and a gap-fill insulating pattern 153. According to embodiments, the first inner insulating spacer 134 and the second inner insulating spacer 152 may cover sidewalls of the direct contacts DC. According to embodiments, the direct contacts DC may face the pad isolation structure IP and the interlayer insulating layer 132 with the first inner insulating spacer 134 therebetween in the second horizontal direction (the Y direction). According to embodiments, the second inner insulating spacer 152 may cover sidewalls of the direct contacts DC, the bit lines BL, and the insulating capping pattern 148 together. In this case, the second inner insulating spacer 152 may cover a surface of a space not filled by the direct contact DC and the first inner insulating spacer 134 in the first recess space R1. For example, the second inner insulating spacer 152 may include portions covering sidewalls of the conductive expanded pads XP and may include portions covering sidewalls of the direct contacts DC. According to embodiments, the gap-fill insulating pattern 153 may fill a space defined by the second inner insulating spacer 152 in the first recess space R1. According to embodiments, the direct contacts DC may be spaced apart from the conductive expanded pads XP with the second inner insulating spacer 152 and the gap-fill insulating pattern 153 therebetween.

According to embodiments, the IC device 100 may include intermediate insulating spacer 154 and outer insulating spacer 156. The intermediate insulating spacer 154 covers portions of the second inner insulating spacer 152, which covers both sidewalls of the bit line BL and both sidewalls of the insulating capping pattern 148 and extends in the second horizontal direction (the Y direction). The outer insulating spacer 156 covers both sidewalls of the intermediate insulating spacer 154 and extends in the second horizontal direction (the Y direction). In this case, the outer insulating spacer 156 may cover both sidewalls of the interlayer insulating layer 132 together. According to embodiments, the second inner insulating spacer 152, the intermediate insulating spacer 154, and the outer insulating spacer 156 may constitute the spacer structure SP1. According to embodiments, the bit line BL, the insulating capping pattern 148 on the bit line BL, and the spacer structure SP1 covering both sidewalls of the bit line BL and the insulating capping pattern 148 may constitute the bit line structure BLS. According to embodiments, the bit line structures BLS may be spaced apart from each other in the first horizontal direction (the X direction) and extend to be parallel to each other in the second horizontal direction (the Y direction).

According to embodiments, the first inner insulating spacer 134 may include undoped polysilicon, a silicon oxide layer, a silicon nitride layer, or combinations thereof. According to embodiments, the second inner insulating spacer 152 may include a silicon nitride layer. According to embodiments, the intermediate insulating spacer 154 may include a silicon oxide layer, an air spacer (e.g., an air gap), or combinations thereof. In this specification, the term “air” may refer to the atmosphere or other gases that may exist during a manufacturing process. According to embodiments, the outer insulating spacer 156 may include a silicon nitride layer.

According to embodiments, a plurality of second recess spaces R2 may be formed in a partial region between the bit line structures BLS. According to embodiments, the conductive contact plugs CP may be located in the second recess spaces R2. According to embodiments, each of the conductive contact plugs CP may contact the conductive expanded pad XP. In this case, each of the conductive contact plugs CP may at least partially overlap the conductive expanded pad XP in the vertical direction (the Z direction).

According to embodiments, the second recess spaces R2 may pass through the conductive expanded pads XP, and portions of the conductive contact plugs CP may respectively extend into the conductive expanded pads XP. According to embodiments, lower surfaces of the conductive contact plugs CP may be located at a vertical level lower than that of upper surfaces of the conductive expanded pads XP.

According to embodiments, the conductive contact plugs CP may include a portion contacting the outer insulating spacer 156, a portion contacting the second inner insulating spacer 152, and a portion contacting the gap-fill insulating pattern 153.

According to embodiments, the conductive contact plugs CP may include a semiconductor material doped with impurities, a metal, a conductive metal nitride, or combinations thereof. According to embodiments, the conductive contact plugs CP may include a doped polysilicon layer, an epitaxially grown silicon layer, or combinations thereof.

According to embodiments, one conductive expanded pad XP and one conductive contact plug CP overlapping in the vertical direction (the Z direction) may constitute one conductive vertical structure CVS. According to embodiments, the conductive vertical structures CVS may be arranged in the second horizontal direction (the Y direction) between the bit line structures BLS.

According to embodiments, in the IC device 100, one direct contact DC and a pair of conductive vertical structures CVS facing each other in the first horizontal direction (the X direction) with the one direct contact DC therebetween may be connected to different active regions ACT, among the active regions ACT.

According to embodiments, a plurality of third recess spaces R3 may be formed in a partial region between the bit line structures BLS. According to embodiments, the separation fences PF may be disposed in the third recess spaces R3. According to embodiments, the separation fences PF may extend in the vertical direction (the Z direction) between the conductive vertical structures CVS. For example, the conductive vertical structures CVS may be spaced apart from each other in the second horizontal direction (the Y direction) with the separation fences PF therebetween.

According to embodiments, in the IC device 100, a pair of conductive vertical structures CVS facing each other in the second horizontal direction (the Y direction) with one separation fence PF therebetween may be respectively connected to different active regions ACT, among the active regions ACT.

According to embodiments, a vertical level of the lowermost surface of the separation fences PF may be lower than a vertical level of the lowermost surface of the conductive expanded pads XP. In this case, the vertical level of the lowermost surface of the separation fences PF may be lower than a vertical level of the lowermost surface of the conductive contact plugs CP. For example, the separation fences PF may pass through the conductive contact plugs CP and the conductive expanded pads XP in the vertical direction (the Z direction).

According to embodiments, the separation fences PF may pass through the upper surface 110U of the substrate 110. For example, the vertical level of the lowermost surface of the separation fences PF may be lower than the vertical level of the upper surface 110U of the substrate 110. In some embodiments, the separation fences PF may overlap the word line structure WLS at least partially in the vertical direction (the Z direction). For example, the separation fences PF may pass through the word line structure 120 buried in the substrate 110 in the vertical direction (the Z direction). According to embodiments, the separation fences PF may include a silicon nitride layer.

According to embodiments, the separation fences PF may have sidewalls extending linearly. For example, the sidewalls of the separation fences PF may be substantially perpendicular to the horizontal directions (the X direction and the Y direction). According to embodiments, the separation fences PF may extend in the vertical direction (the Z direction) between the vertical structures CVS, and in this case, the separation fences PF may have a sidewall extending substantially linearly in the vertical direction (the Z direction). Here, the vertical direction (the Z direction) may be, for example, a direction in which the separation fences PF extend to separate the vertical structures CVS from each other, and the sidewalls of the separation fences PF may extend at a slightly inclined angle in the horizontal direction (the X direction and/or the Y direction) with respect to the vertical direction (the Z direction). According to embodiments, the separation fences PF may have a single central axis CXP perpendicular to the substrate 110.

According to embodiments, the sidewalls of the separation fences PF may not include a portion which is concave inwardly or convex outwardly based on a linearly extending surface. According to embodiments, the sidewalls of the separation fences PF may not have a step structure with respect to an extending direction.

According to embodiments, the sidewalls of the separation fences PF may include a first portion P1 contacting an interface between the conductive expanded pads XP and the contact plugs CP. According to embodiments, the sidewalls of the separation fences PF may extend linearly from the first portion P1. For example, the sidewalls of the separation fences PF may extend linearly in the vertical direction (the Z direction). Accordingly, a stable electrical connection may be made between the conductive expanded pads XP and the conductive contact plugs CP constituting one vertical structure CVS, and stable electrical separation may be made between the different conductive vertical structures CVS spaced apart from each other with the plurality of isolation fences PF therebetween. Accordingly, electrical reliability of the IC device 100 having a device region having an area reduced according to downscaling may be improved.

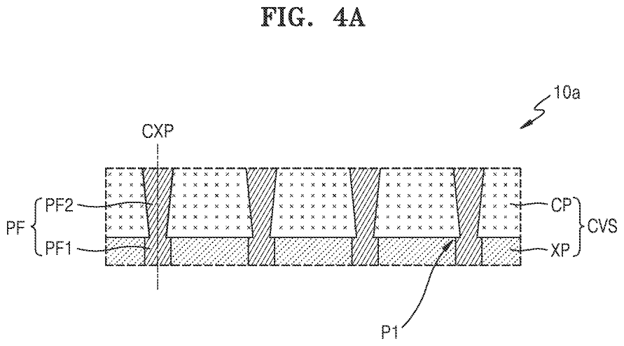

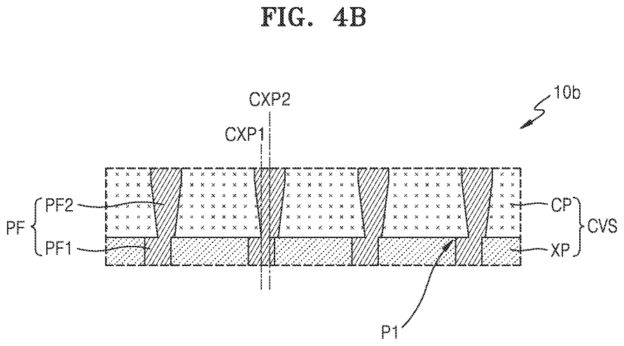

FIGS. 4A and 4B are enlarged views of portions of IC devices 10a and 10b of the related art, corresponding to portion “EX1” of FIG. 2B. Referring to FIGS. 4A and 4B, sidewalls of the separation fences PF of the IC devices 10a and 10b of the related art do not have a flat surface.

Referring to FIG. 4A, the separation fence PF of the IC device 10a according to the related art may include a portion concave inwardly and a portion protruding outwardly with respect to the central axis CXP of the separation fence PF. For example, the separation fence PF of the IC device 10a according to the related art may have a step structure between a portion PF1 in contact with the conductive expanded pads XP and a portion PF2 in contact with the conductive plugs CP. For example, the sidewall of the separation fence PF of the IC device 10a according to the related art may not extend linearly from a first portion P1 in contact with an interface between the conductive expanded pads XP and the contact plugs CP.

Referring to FIG. 4B, in the separation fence PF of the IC device 10b according to another related art, a first central axis CXP1 that is a central axis of a portion PF1 in contact with the conductive expanded pads XP may not be aligned with (i.e., offset from) a second central axis CXP2 that is a central axis of a portion PF2 in contact with the conductive plugs CP. For example, in the separation fence PF of the IC device 10b according to the related art, the portion PF1 in contact with the conductive expanded pads XP may only partially overlap the portion PF2 in contact with the conductive plugs CP in the vertical direction (the Z direction). For example, the sidewall of the separation fence PF of the IC device 10b according to the related art may not linearly extend at the first portion in contact with the interface between conductive expanded pads XP and the contact plugs CP.

For example, the separation fence PF of the IC devices 10a and 10b according to the related art may include a portion (e.g., the first portion P1) having a horizontal area narrower than other portions.

According to embodiments, the separation fence PF of the IC device 100 may have sidewalls extending linearly, and thus, even when the device region has a reduced area, structural and electrical stability may be improved and a reliable electrical connection between the conductive regions may be secured.

According to embodiments, each of the separation fences PF may be an integral structure that is in contact with the conductive expanded pads XP and the conductive plugs CP. For example, each of the separation fences PF may be located between two adjacent conductive vertical structures CVS, as a single structure.

In some other embodiments, the separation fences PF may include a plurality of layers. For example, the separation fences PF may include a first sub-fence filling a lower portion of the third recess space R3 and a second sub-fence filling an upper portion of the second recess space R2 on the first sub-fence. In this case, similarly, in the sidewalls of the separation fences PF, a portion in which the interface between the first sub-fence and the second sub-fence is formed may extend linearly in the vertical direction (the Z direction). For example, the separation fences PF may include a third sub-fence conformally covering lower and side surfaces of the third recess space R3 and a fourth sub-fence filling a space defined by the third sub-fence in the third recess space R3. In this case, sidewalls of the third sub-fence that are in contact with the conductive expanded pads XP and the conductive plugs CP together may extend linearly in the vertical direction (the Z direction).

According to embodiments, the conductive landing pads LP may be disposed on the conductive plugs CP. According to embodiments, each of the conductive landing pads LP may be in contact with a conductive plug CP and extend in the vertical direction (the Z direction) on the conductive plug CP. According to embodiments, each of the conductive landing pads LP may at least partially overlap a conductive plug CP in the vertical direction (the Z direction).

According to embodiments, each of the conductive landing pads LP may have a sidewall facing the bit line structure BLS in the first horizontal direction (the X direction). According to embodiments, the conductive landing pads LP may partially overlap the bit line structures BLS in the vertical direction (the Z direction). According to embodiments, the conductive landing pads LP may extend in the vertical direction (the Z direction) to pass through spaces between the bit line structures BLS on the conductive plugs CP, and may partially cover upper portions of the bit line structures BLS.

According to embodiments, each of the conductive landing pads LP may have a sidewall facing the separation fence PF in the second horizontal direction (the Y direction).

According to embodiments, each of the conductive landing pads LP may include a conductive barrier layer 174 and a conductive layer 176. According to embodiments, the conductive barrier layer 174 may include a Ti/TiN stack structure. According to embodiments, the conductive layer 176 may include metal. For example, the conductive layer 176 may include tungsten (W).

According to embodiments, the conductive landing pads LP may have a pattern shape of a plurality of islands in a plan view. According to embodiments, the conductive landing pads LP may be electrically insulated from each other by an insulating layer 180 filling an upper recess space R4 therearound.

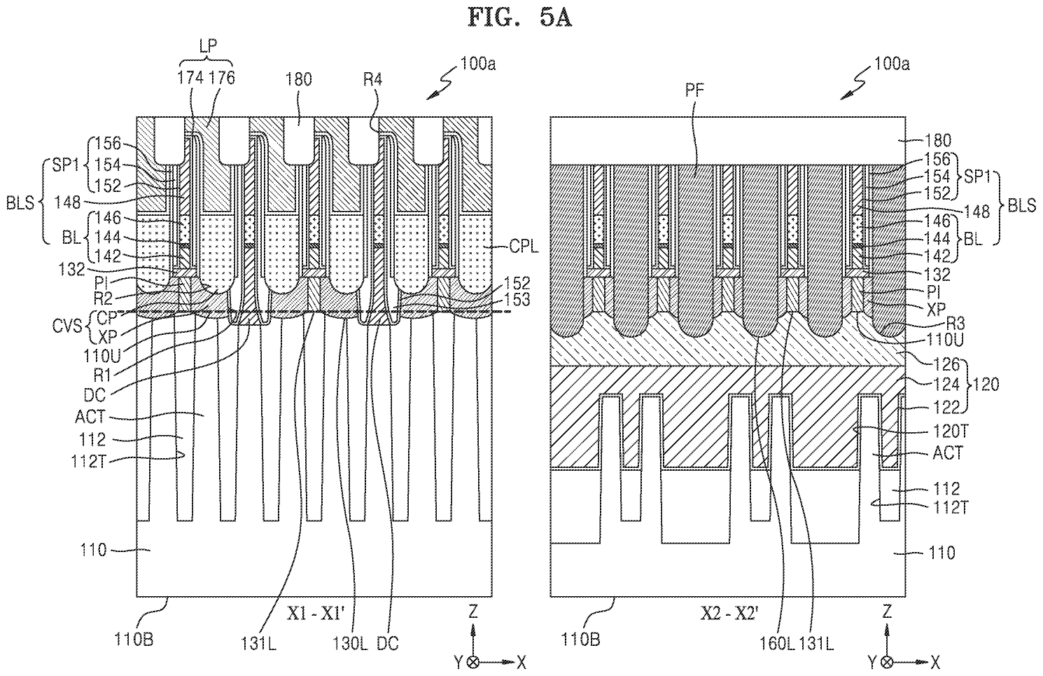

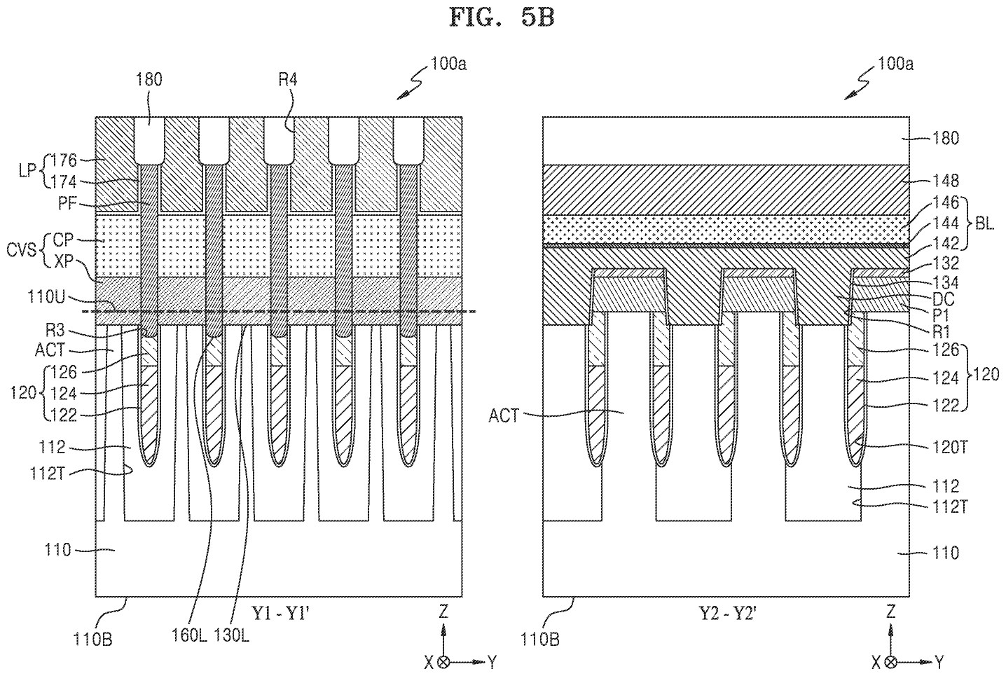

FIGS. 5A and 5B are diagrams illustrating an IC device 100a according to some other embodiments, in which FIG. 5A is a cross-sectional view of some components, taken along lines X1-X1′ and X2-X2′ of FIG. 1 and FIG. 5B is a cross-sectional view of some components, taken along lines Y1-Y1′ and Y2-Y2′ of FIG. 1. A difference between the IC device 100a according to FIGS. 5A and 5B and the IC device 100 according to FIGS. 2A and 2B lies in whether the lower surface 130L of the conductive expanded pad XP is at a vertical level lower than that of the upper surface 110U of the substrate 110.

Referring to FIGS. 5A and 5B, lower surfaces 130L of the conductive expanded pads XP may be at a lower vertical level than that of the lower surface 131L of the pad isolation structures PI. In this case, the lower surface 131L of the pad isolation structures PI may be at the same level as that of the upper surface 110U of the substrate 110 in the vertical direction (the Z direction). According to embodiments, each of the conductive expanded pads XP may extend into and contact one of the active regions ACT.

According to embodiments, the lower surface of the first recess space R1 may be at a lower vertical level than that of the lower surface 130L of the conductive expanded pads XP. For example, even when the conductive expanded pads XP pass through the upper surface 110U of the substrate 110 and contact the active regions ACT, the conductive expanded pads XP may be stably spaced apart from the direct contact DC with second inner insulating spacer 152 and the gap-fill insulating pattern 153 therebetween.

According to embodiments, the lower surface 160L of the separation fence PF of the IC device 100a may be at a lower vertical level than that of the lower surface 130L of the conductive expanded pad XP.

Hereinafter, a method of manufacturing the IC device 100 according to embodiments is described.

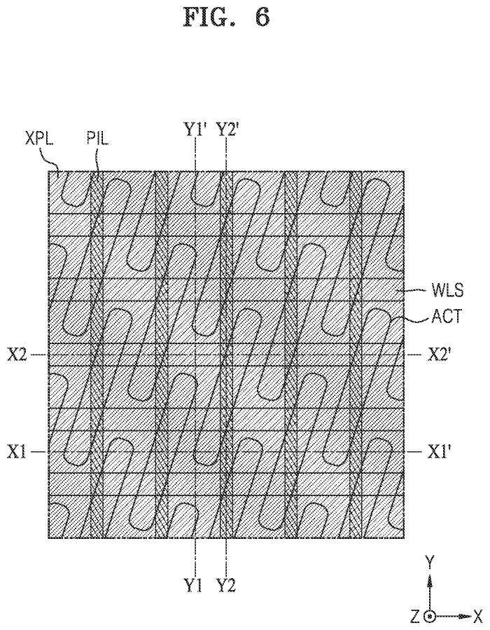

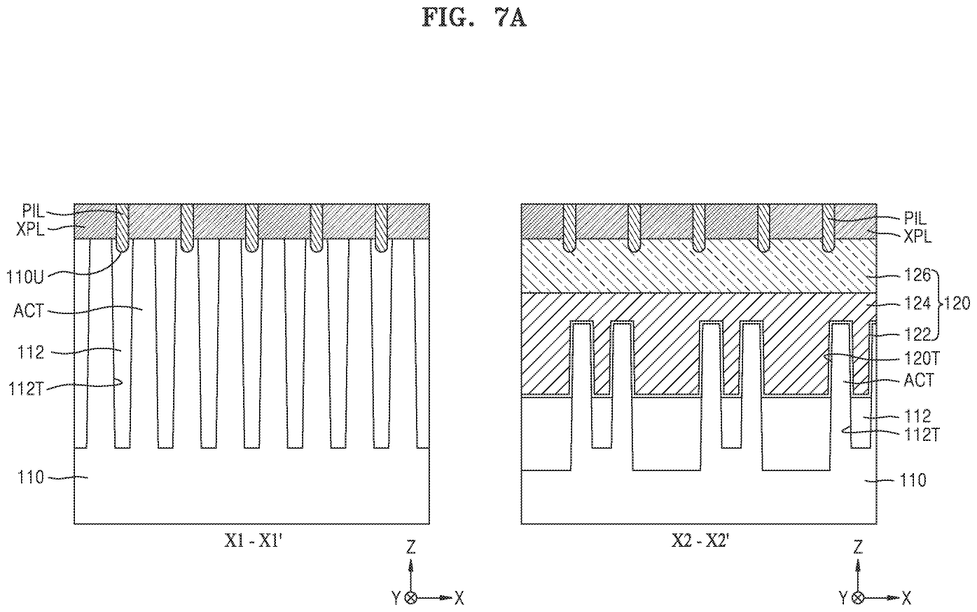

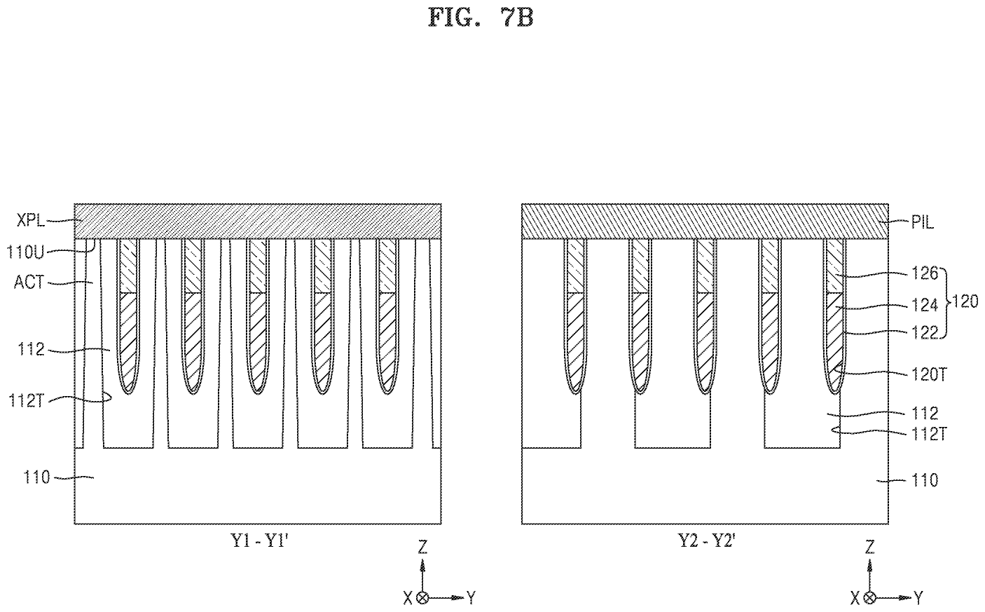

FIGS. 6 to 16B are diagrams illustrating sequential processes of a method of manufacturing the IC device 100 according to embodiments, in which FIGS. 6, 8, 13, and 15 are schematic plan layout views illustrating some components of a memory cell array region of the IC device 100, FIGS. 7A, 9A, 10A, 11A, 12A, 14A, and 16A are cross-sectional views of some components, taken along lines X1-X1′ and X2-X2′, and FIGS. 7B, 9B, 10B, 11B, 12B, 14B, and 16B are cross-sectional views of some components, taken along lines Y1-Y1′ and Y2-Y2′ of FIG. 1. The method of manufacturing the IC device 100 illustrated with reference to FIGS. 1, 2A, 2B, and 3 are described with reference to FIGS. 6 to 16B.

Referring to FIGS. 6, 7A, and 7B, the device isolation trench 112T may be formed on the substrate 110, and the device isolation layer 112 may be formed in the device isolation trench 112T. The active regions ACT may be defined by the device isolation layer 112 on the substrate 110.

The word line trenches 120T may be formed in the substrate 110. The word line trenches 120T may extend to be parallel to each other in the first horizontal direction (the X direction) and may have a line shape crossing the active region ACT. The gate dielectric layer 122, the word line 124, and the buried insulating layer 126 may be sequentially formed inside each of the word line trenches 120T. Before or after forming the word lines 124, an ion implantation process may be performed to form the source/drain regions on the active regions ACT.

A plurality of conductive expanded pad lines XPL and a plurality of pad isolation line structures PIL extending to be parallel to each other in the second horizontal direction (the Y direction) on the substrate 110 may be alternately arranged in the first horizontal direction (the X direction). According to embodiments, the conductive expanded pad lines XPL and the pad isolation line structures PIL may be formed to cover an upper surface of the active regions ACT, an upper surface of the device isolation layer 112, and an upper surface of the buried insulating layer 126.

According to embodiments, a conductive layer may be formed by uniformly applying a material for forming the conductive expanded pad lines XPL on the substrate 110, and then a partial region of the conductive layer may be etched to form a trench extending in the second horizontal direction (the Y direction) for the pad isolation line structures PIL, and in this case, the trench may pass through a portion of the upper surface 110U of the substrate 110. For example, the conductive layer may be formed through a physical vapor deposition (PVD) process, an atomic layer deposition (ALD) process, a chemical vapor deposition (CVD) process, a physical vapor deposition (PVD) process, a plasma enhanced CVD (PECVD) process, a low pressure CVD (LPCVD) process, or the like. Thereafter, the trench may be filled with the pad isolation line structure PIL and a planarization process may be performed thereon. For example, the pad isolation line structure PIL may be formed through an ALD process, a CVD process, a PVD process, a PECVD process, an LPCVD process, or the like.

In some other embodiments, an insulating layer may be formed by uniformly applying an insulating material to the substrate 110 and a partial region of the insulating layer may be etched to form a trench extending in the second horizontal direction (the Y direction), and in this case, the trench may pass through a portion of the upper surface 110U of the substrate 110. Thereafter, the trench may be filled with the conductive expanded pad line XPL, and a planarization process may be performed thereon. For example, the insulating layer may be formed through an ALD process, a CVD process, a PVD process, a PECVD process, an LPCVD process, or the like. For example, the conductive expanded pad line XPL may be formed through a damascene process or the like. Thereafter, the IC device 100a described above with reference to FIGS. 5A and 5B may be manufactured according to a manufacturing method described below.

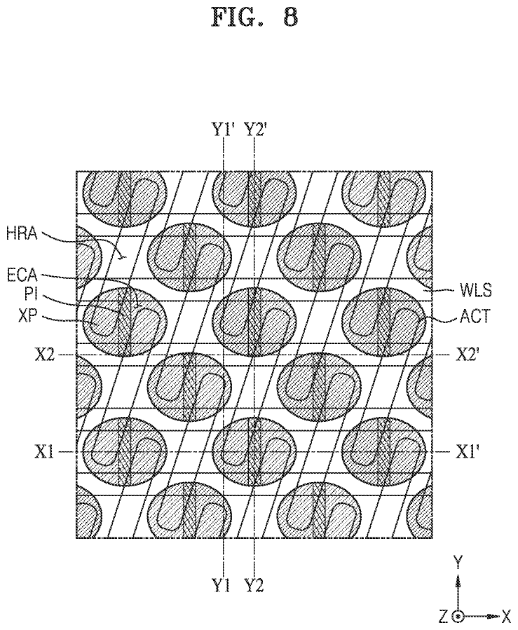

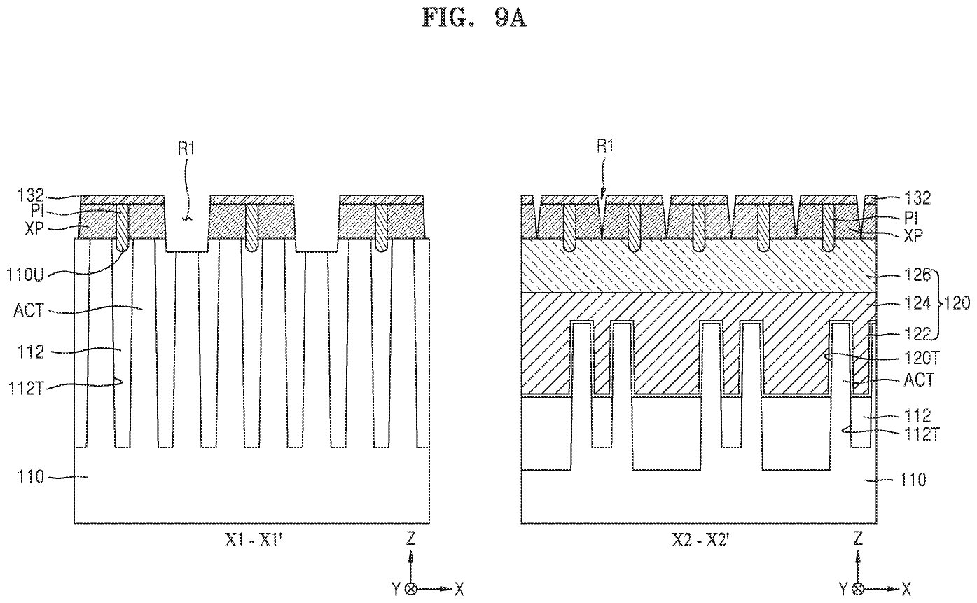

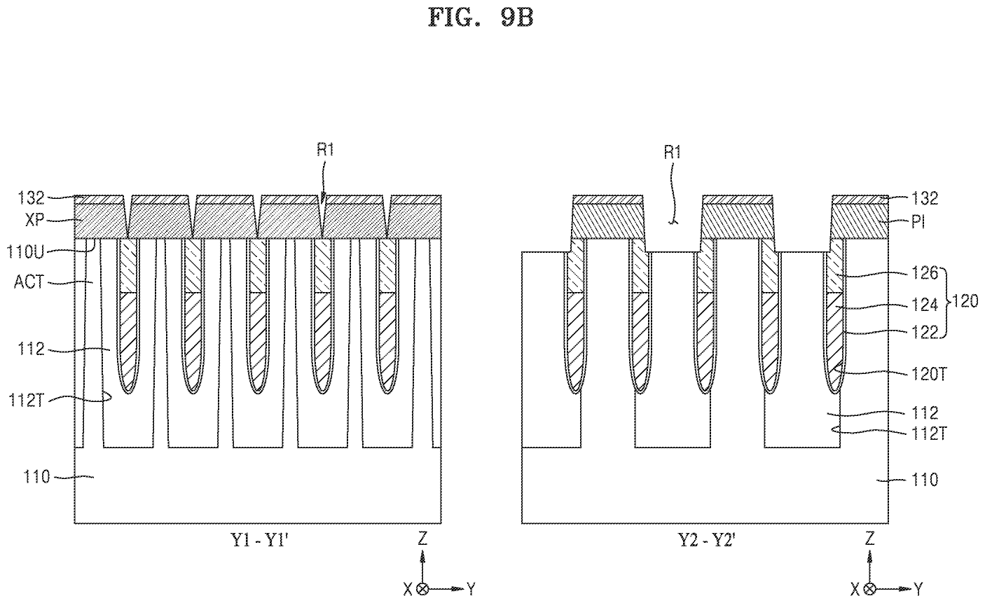

Referring to FIGS. 8, 9A, and 9B, in a resultant structure of FIGS. 6, 7A, and 7B, the interlayer insulating layer 132 covering the upper surface of the conductive expanded pad lines XPL and the upper surface of the pad isolation line structures PIL is formed, and then, the first recess space R1 may be formed in the active region ACT in a partial region of the substrate 110. Accordingly, the engraved recess space HRA exposing a portion of each of the active regions ACT and the embossed cell region ECA including the conductive expanded pads XP and the pad isolation structures PI may be formed. For example, in the process of forming the first recess space R1, portions of the conductive expanded pad lines XPL and the pad isolation line structures PIL may be removed to form the conductive expanded pads XP and the pad isolation structures PI.

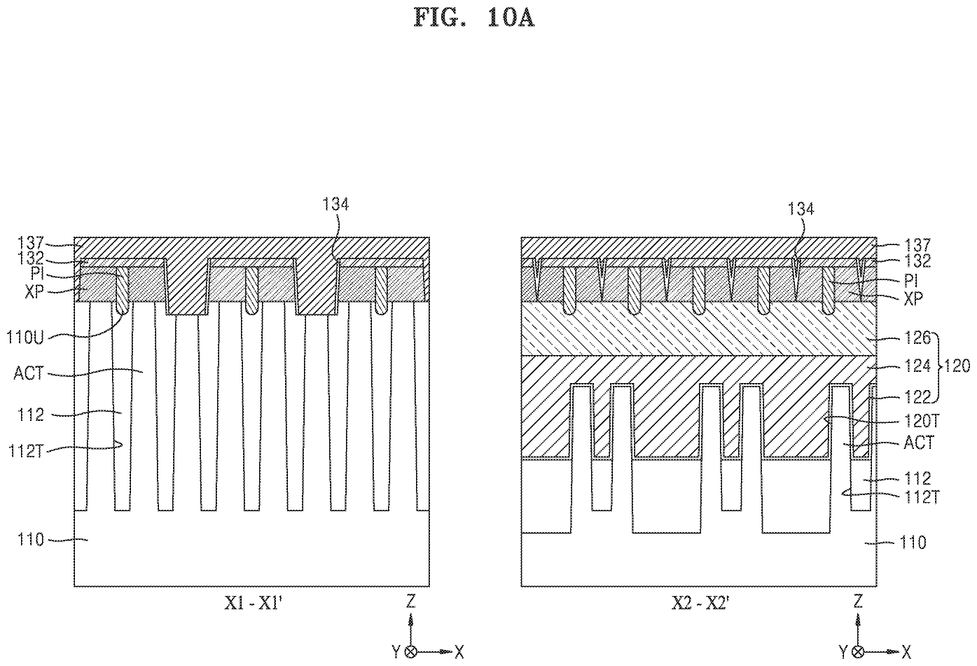

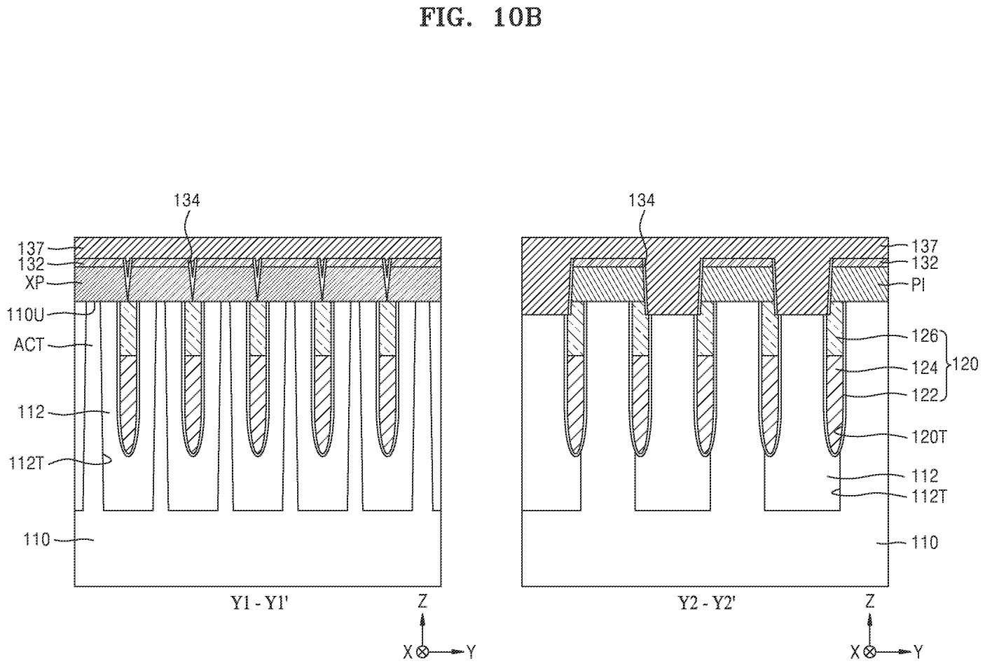

Referring to FIGS. 10A and 10B, after forming the first inner insulating spacer 134 conformally covering the surface exposed through the first recess space R1, the first inner insulating spacer 134 covering the lower surface of the first recess space R1 may be removed through etching to expose the active regions ACT again. In this case, the first inner insulating spacer 134 may include a portion covering sidewalls of the interlayer insulating layer 132, sidewalls of the conductive expanded pad XP, and sidewalls of the pad isolation structure PI constituting the sidewalls of the first recess space R1. The first inner insulating spacer 134 may include a portion covering the device isolation layer 112 and the buried insulating layer 126 constituting the sidewalls of the first recess space R1.

Thereafter, a remaining portion of the first recess space R1 may be filled with the conductive layer 137 for forming the direct contact DC. For example, the conductive layer 137 for forming the direct contact DC may be formed to have a thickness sufficient to fill the first recess space R1 and cover the upper surface of the interlayer insulating layer 132.

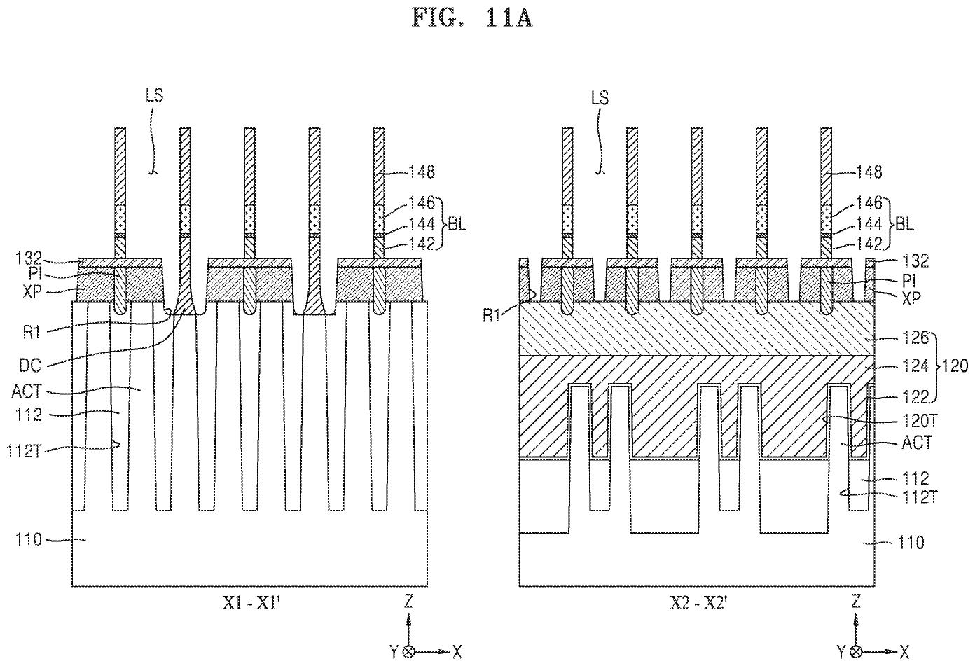

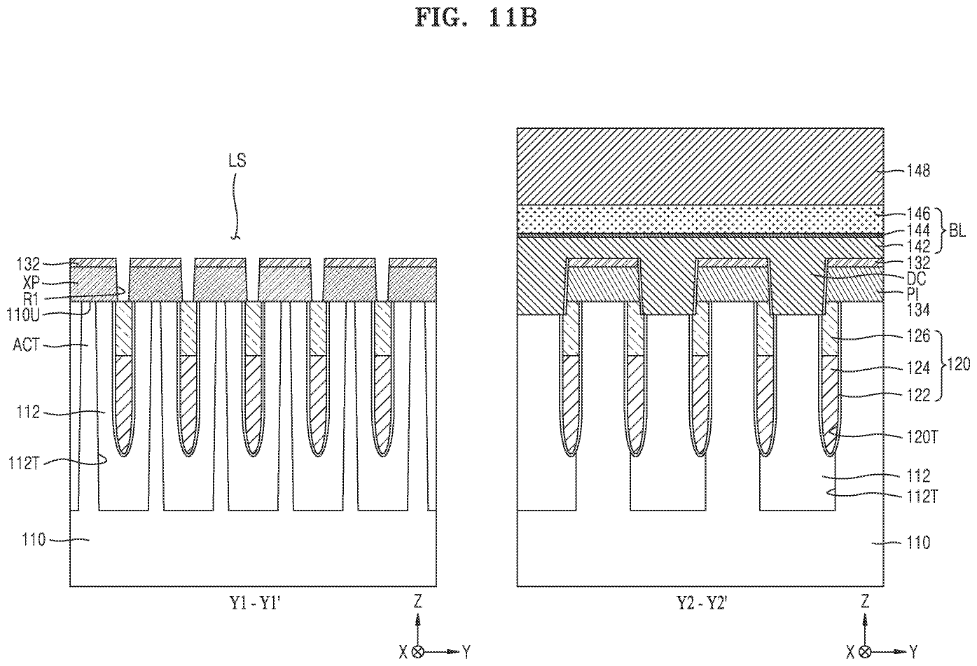

Referring to FIGS. 11A and 11B, in a resultant structure of FIGS. 10A and 10B, an intermediate conductive layer, an upper intermediate conductive layer, and the insulating capping patterns 148 may be formed on the conductive layer 137 for forming the direct contact DC. According to embodiments, the intermediate conductive layer and the upper conductive layer may be formed to uniformly cover the entire conductive layer 137 for forming the direct contact DC, and the insulating capping patterns 148 may include line patterns extending in the second horizontal direction (the Y direction).

Thereafter, a portion of each of the conductive layer 137 for forming the direct contact DC, the intermediate conductive layer, and the upper conductive layer may be etched using the insulating capping patterns 148 as an etching mask to form the bit lines BL including the lower conductive lines 142, the intermediate conductive lines 144, and the upper conductive lines 146 and the direct contact DC. For example, the bit lines BL may include portions remaining after portions of the conductive layer 137 for forming the direct contact DC, the intermediate conductive layer, and the upper conductive layer are removed. After the etching process is performed, the area of the engraved recess space HRA may be further expanded in a plan view.

After the bit lines BL are formed, a portion of the first recess space R1 may be exposed again in the vicinity of the direct contact DC. A line space LS extending in the second horizontal direction (the Y direction) may be defined between each of the bit lines BL.

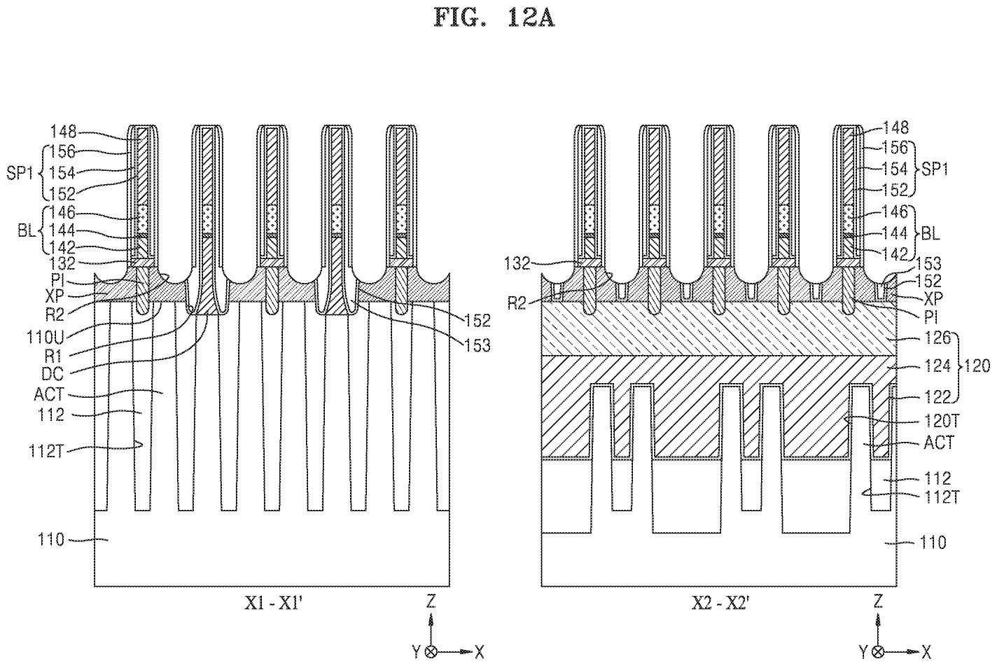

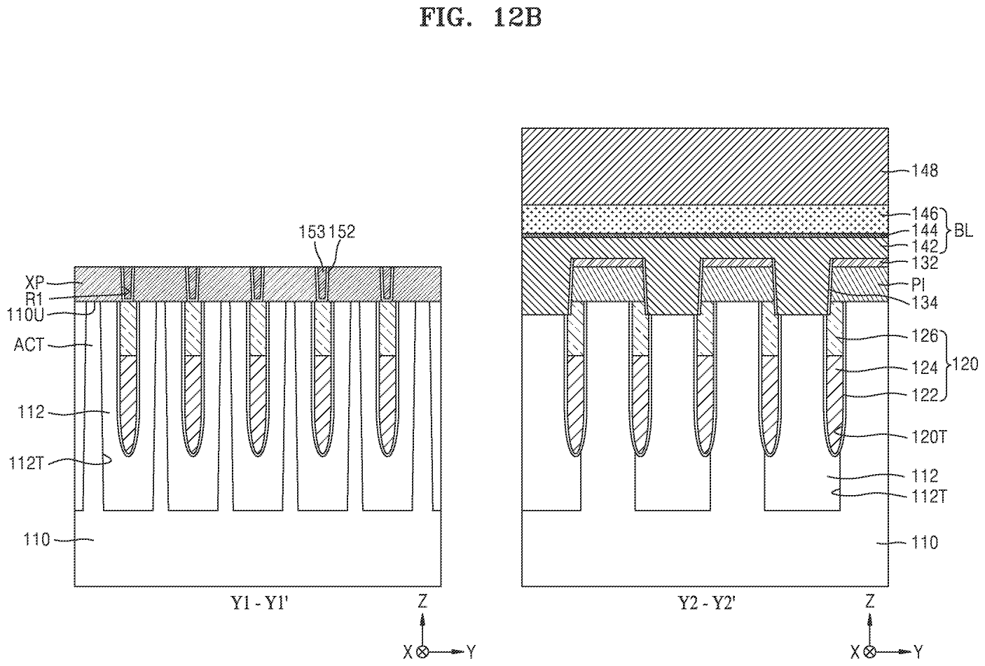

Referring to FIGS. 12A and 12B, a spacer structure SP1 covering the sidewalls of the bit lines BL and the sidewalls of the insulating capping patterns 148 may be formed to form the bit line structure BLS.

According to embodiments, in a resultant structure of FIGS. 11A and 11B, the second inner insulating spacer 152 conformally covering the exposed surface may be formed. The second inner insulating spacer 152 may be formed to conformally cover each of the direct contact DC, the lower conductive line 142, the intermediate conductive line 144, the upper conductive line 146, and the insulating capping patterns 148. The second inner insulating spacer 152 may include a silicon nitride layer. For example, the second inner insulating spacer 152 may be formed through a CVD process or an ALD process.

Thereafter, a preliminary gap-fill insulating layer may be formed on the sidewalls of the bit lines BL, the insulating capping patterns 148, and the direct contacts DC, while filling a remaining space of the first recess space R1 on the second inner insulating spacer 152. In embodiments, the preliminary gap-fill insulating layer may include a silicon nitride layer. For example, the preliminary gap-fill insulating layer may be formed through a CVD or ALD process.

Thereafter, the preliminary gap-fill insulating layer may be isotropically etched to form the gap-fill insulating pattern 153 including a remaining portion of the preliminary gap-fill insulating layer. During isotropic etching of the preliminary gap-fill insulating layer, the second inner insulating spacer 152 may serve as an etch stop layer.

Thereafter, an intermediate insulating spacer layer conformally covering the exposed surfaces is formed by using a CVD or ALD process, the intermediate insulating spacer layer may be anisotropically etched to form the intermediate insulating spacers 154 from the intermediate insulating spacer layer.

While the intermediate insulating spacer layer is anisotropically etched to form the intermediate insulating spacers 154, a portion of the second inner insulating spacer 152 and a portion of the interlayer insulating layer 132 may be removed. As a result, a portion of the substrate 110, a portion of the second inner insulating spacer 152, and a portion of the gap-fill insulating pattern 153 may be exposed through the line spaces LS. The intermediate insulating spacers 154 may cover the sidewalls of the bit line BL and the sidewalls of the insulating capping pattern 148 on the second inner insulating spacer 152, respectively.

According to embodiments, the intermediate insulating spacers 154 may include a material different from a material of the second inner insulating spacer 152 and a material of the gap-fill insulating pattern 153. The intermediate insulating spacers 154 may include a material having an etch selectivity with respect to each of the second inner insulating spacer 152 and the gap-fill insulating pattern 153. For example, the intermediate insulating spacers 154 may include a silicon oxide layer.

Thereafter, an outer insulating spacer layer conformally covering the exposed surfaces may be formed using a CVD or ALD process. The outer insulating spacer layer may include a material having an etch selectivity with respect to the intermediate insulating spacers 154. For example, the outer insulating spacer layer may include a silicon nitride layer.

Thereafter, the outer insulating spacer 156 may be formed through an etching process to form the bit line structure BLS, and the second recess space R2 extending in the second horizontal direction (the Y direction) between the bit line structures BLS and exposing upper surfaces of the conductive expanded pads XP may be formed. For example, the interlayer insulating layer 132 covering the upper surface of the conductive expanded pad XP may be removed. For example, the outer insulating spacer 156 may include a portion covering the intermediate insulating spacer 154, a portion covering the second inner insulating spacer 152, and a portion covering the interlayer insulating layer 132.

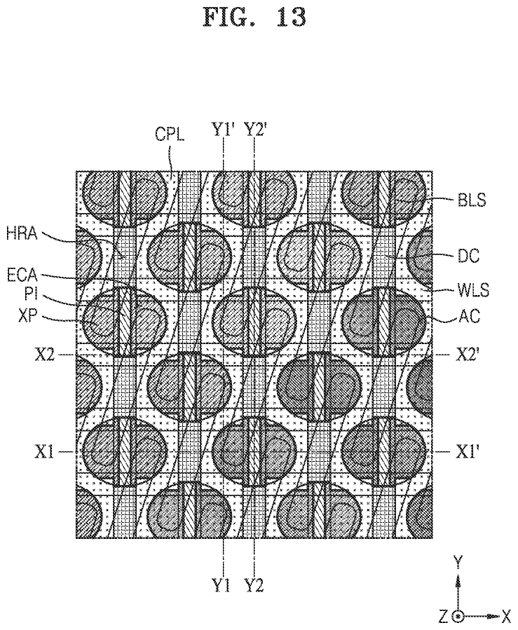

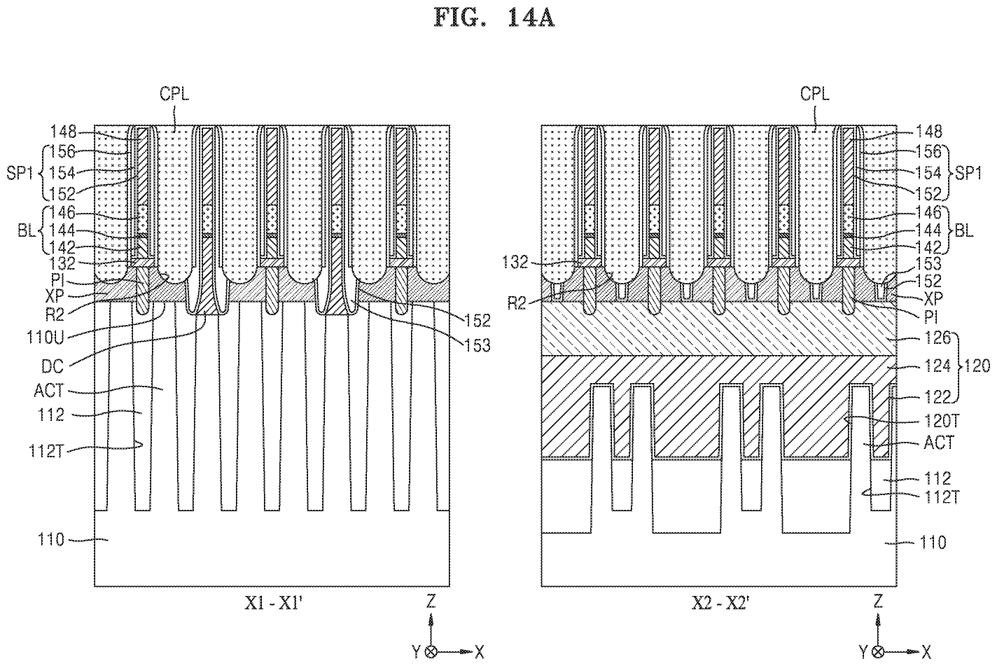

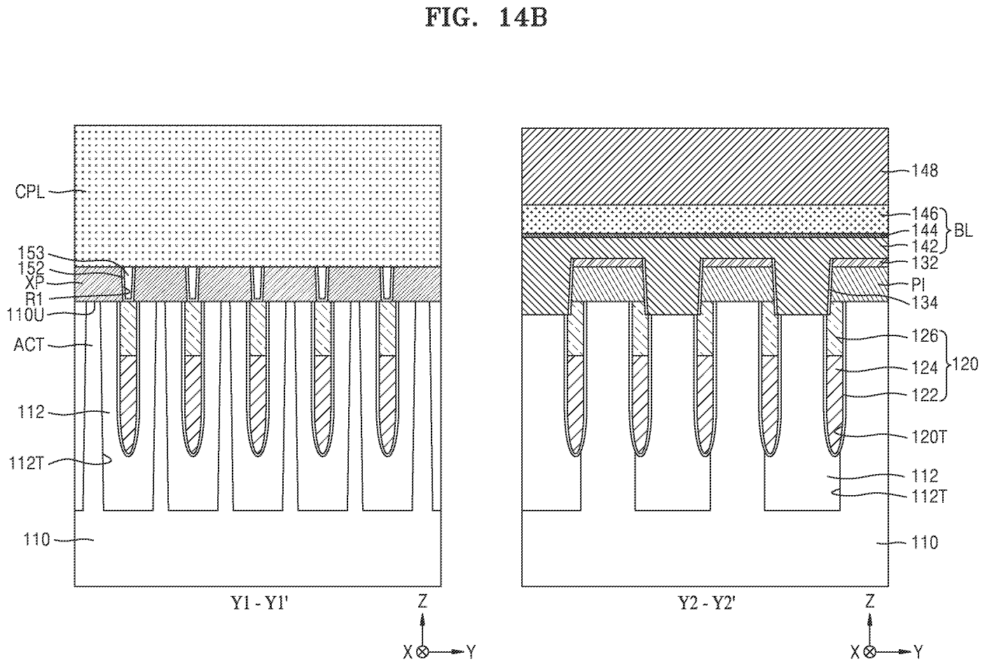

Referring to FIGS. 13, 14A, and 14B, in a resultant structure of FIGS. 12A and 12B, the second recess space R2 may be filled with a conductive film and then flattened to form conductive lines CPL extending in the second horizontal direction (the Y direction). According to embodiments, the conductive lines CPL may be spaced apart from each other in the first horizontal direction (the X direction) with the bit line structures BLS therebetween.

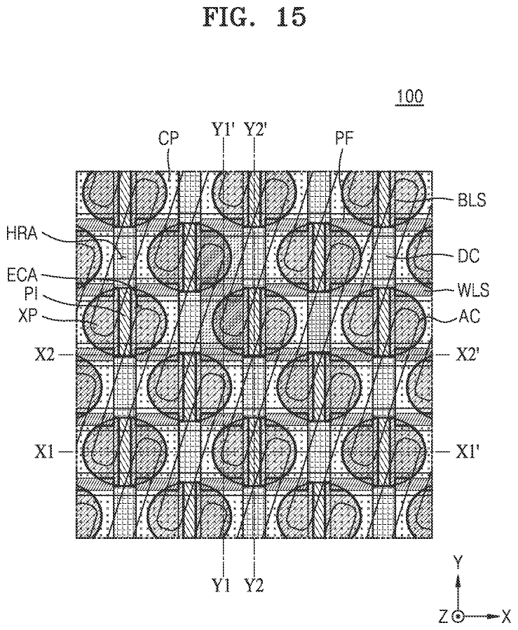

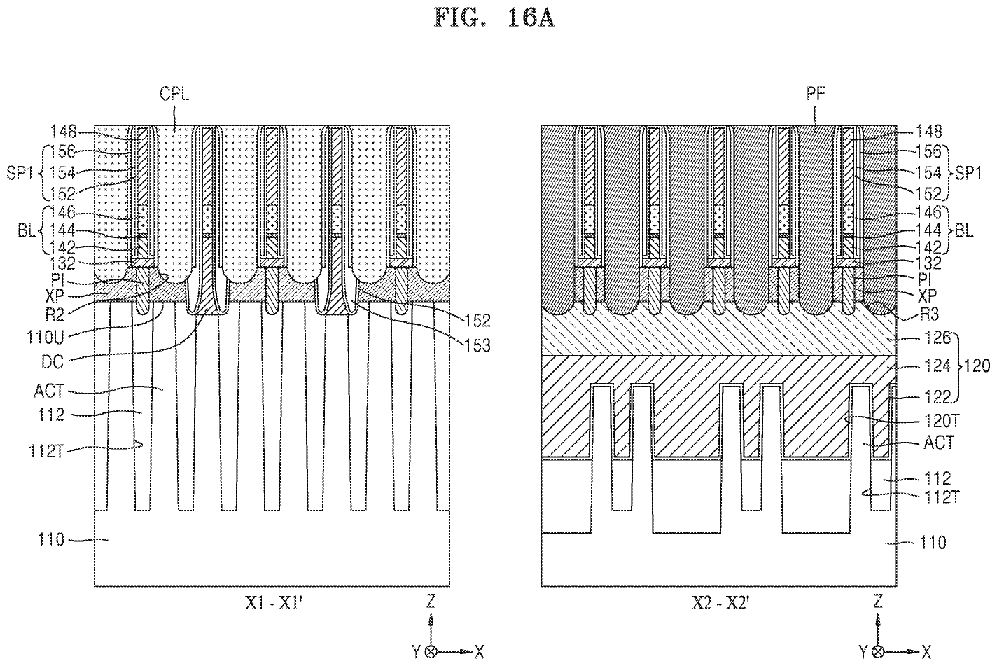

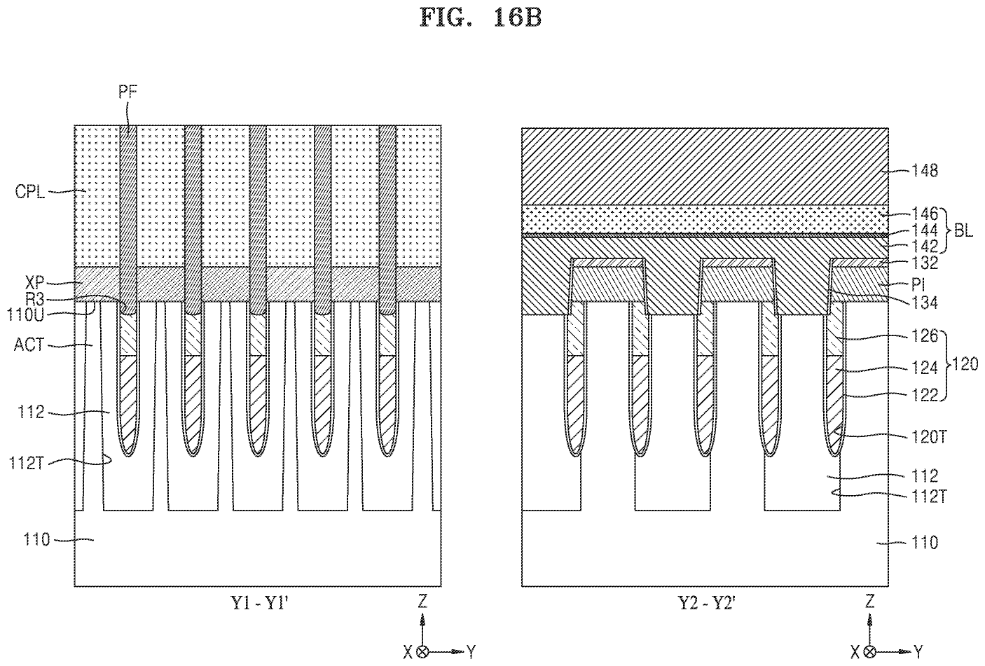

Referring to FIGS. 15, 16A, and 16B, in a resultant structure of FIGS. 13, 14A, and 14B, the third recess space R3 may be formed in a partial region between the bit line structures BLS. According to embodiments, the third recess space R3 may pass through the conductive expanded pads XP and the conductive lines CPL together, and accordingly, the conductive plugs CP may be formed. According to embodiments, side surfaces of the conductive expanded pads XP and side surfaces of the conductive plugs CP exposed by the third recess space R3 may be formed to be flat. Thereafter, the separation fences PF filling the third recess space R3 may be formed. For example, the separation fence PF may be formed through an ALD or CVD process.

According to the manufacturing method of the IC device 100 according to embodiments, in the process of forming the third recess space R3, the conductive expanded pads XP adjacent to each other and the conductive contact plugs CP adjacent to each other may be separated through a single process of forming the third recess space R3. For example, a process of separating two adjacent conductive expanded pads XP and a process of separating the adjacent conductive contact pads CP in the second horizontal direction (the Y direction) may be performed as a single process. Accordingly, process costs may be reduced, and the sidewall of the separation fence PF is formed to be flat, so that structural stability and electrical reliability of the IC device 100 may be improved.

Referring to FIGS. 1, 2A, and 2B, in a resultant structure of FIGS. 15, 16A, and 16B, the upper surfaces of the conductive plugs CP may be etched back in a partial region between the bit line structures BLS to expose a portion of the second recess space R2, and then, the conductive barrier layer 174 conformally covering the exposed surfaces may be formed. For example, the conductive barrier layer 174 may partially fill the second recess space R2 and may cover upper surfaces of the conductive plugs CP and portions of the sidewalls and upper surfaces of the bit line structures BLS. Thereafter, the conductive layer 176 may be formed by forming a metal layer having a thickness sufficient to fill the second recess space R2 on the conductive barrier layer 174.

Thereafter, a mask pattern exposing a portion of the conductive layer 176 may be formed on the conductive layer 176, and the conductive layer 176, the conductive barrier layer 174, the spacer structure SP1, and the insulating capping pattern 148 may be etched using the mask pattern as an etching mask to form the upper recess space R4. The mask pattern may include a silicon nitride layer, but is not limited thereto.

An upper surface of each of the conductive landing pads LP defined by the upper recess space R4 may have a shape of a plurality of island patterns. Portions of the conductive landing pads LP extending in the horizontal direction outside the second recess space R2 may configure the conductive landing pads LP illustrated in FIG. 1.

After the conductive landing pads LP are formed, the conductive barrier layer 174 and the conductive layer 176 included in each of the conductive landing pads LP may form each of the lower conductive line 142, the intermediate conductive line 144, and the upper conductive line 146 included in the bit line BL with the second inner insulating spacer 152, the intermediate insulating spacer 154, and the outer insulating spacer 156 therebetween.

The upper recess space R4 around the conductive landing pads LP may be filled with the insulating layer 180 to electrically insulate the conductive landing pads LP from each other. Thereafter, a plurality of capacitor lower electrodes electrically connectable to the conductive landing pads LP may be formed on the insulating layer 180.

In the above, the method of manufacturing the IC device 100a by forming the embossed cell region ECA and the engraved recess space HRA through the first recess space R1 and forming the direct contact DC in a partial region of the engraved recess space HRA. has been described, but is not limited thereto. For example, as described above with reference to FIGS. 6, 7A, and 7B, after the conductive expanded pad lines XPL and the pad isolation line structures PIL are formed, the interlayer insulating layer 132 may be formed, and direct contact holes may be formed in a partial region. In this case, the direct contact hole may correspond to the engraved recess space HRA according to embodiments.

While aspects of embodiments have been particularly shown and described, it will be understood that various changes in form and details may be made therein without departing from the spirit and scope of the following claims.

What is claimed is:

1. An integrated circuit (IC) device comprising:
a substrate having a plurality of active regions;
a plurality of word lines extending in a first horizontal direction across the plurality of active regions;
a plurality of bit lines extending on the substrate in a second horizontal direction perpendicular to the first horizontal direction;
a plurality of conductive vertical structures comprising a plurality of conductive expanded pads and a plurality of conductive contact plugs, wherein the plurality of conductive expanded pads are closer to a bottom surface of the substrate than the plurality of bit lines and are in contact with the plurality of active regions, and the plurality of conductive contact plugs extend in a vertical direction and are connected to the plurality of conductive expanded pads between each of the plurality of bit lines; and
a plurality of separation fences separating the plurality of conductive vertical structures from each other, between each of the plurality of bit lines, and having sidewalls extending linearly in contact with the plurality of conductive vertical structures.

2. The IC device of claim 1, wherein lower surfaces of the plurality of separation fences are closer to the bottom surface of the substrate than lower surfaces of the plurality of conductive expanded pads.

3. The IC device of claim 1, wherein each of the plurality of separation fences comprises:
a first portion facing one of the plurality of conductive expanded pads; and
a second portion facing one of the plurality of conductive contact plugs, and
wherein the first portion and the second portion are integrated with each other.

4. The IC device of claim 1, wherein a central axis of each of the plurality of separation fences is perpendicular to the substrate.

5. The IC device of claim 1, wherein lower surfaces of the plurality of conductive expanded pads are coplanar with an upper surface of the substrate.

6. The IC device of claim 1, wherein each of the plurality of conductive expanded pads extends through an upper surface of the substrate.

7. The IC device of claim 1, wherein the plurality of separation fences at least partially overlap the plurality of word lines in the vertical direction.

8. The IC device of claim 1, wherein the plurality of conductive expanded pads comprise any one or any combination of a metal, a doped polysilicon layer, and an epitaxially grown silicon layer.

9. The IC device of claim 1, further comprising:
a plurality of direct contacts connected between the plurality of bit lines and the plurality of active regions; and
a plurality of pad isolation structures spaced apart from each other in the second horizontal direction with the plurality of direct contacts therebetween, and separating the plurality of conductive expanded pads in the first horizontal direction.

10. The IC device of claim 9, further comprising an interlayer insulating layer between the plurality of pad isolation structures and the plurality of bit lines.

11. An integrated circuit (IC) device comprising:
a substrate having a plurality of active regions;
a plurality of word lines extending in a first horizontal direction across the plurality of active regions;
a plurality of conductive expanded pads on the substrate and connected to the plurality of active regions;
a plurality of pad isolation structures located between the plurality of conductive expanded pads;
a plurality of direct contacts connected to the plurality of active regions;
a plurality of bit lines extending in a second horizontal direction perpendicular to the first horizontal direction, on the plurality of direct contacts and the plurality of pad isolation structures, and connected to the plurality of direct contacts;
a plurality of conductive plugs extending in a vertical direction on the plurality of conductive expanded pads and connected to the plurality of conductive expanded pads; and
a plurality of separation fences passing through the plurality of conductive expanded pads and the plurality of conductive plugs, and having sidewalls extending linearly in the vertical direction.

12. The IC device of claim 11, wherein a central axis of each of the plurality of separation fences is perpendicular to the substrate.

13. The IC device of claim 11, wherein lower surfaces of the plurality of conductive expanded pads are coplanar with an upper surface of the substrate.

14. The IC device of claim 11, wherein lower surfaces of the plurality of conductive expanded pads are at a first vertical level, an upper surface of the substrate is at a second vertical level higher than the first vertical level, and a lower surface of the direct contact is at a third vertical level lower than the first vertical level.

15. The IC device of claim 11, wherein the plurality of separation fences at least partially overlap the plurality of word lines in the vertical direction.

16. The IC device of claim 11, further comprising an interlayer insulating layer between the plurality of pad isolation structures and the plurality of bit lines.

17. An integrated circuit (IC) device comprising:
a substrate having a plurality of active regions spaced apart from each other;
a plurality of word lines extending in a first horizontal direction across the plurality of active regions;
a plurality of bit line structures spaced apart from each other in the first horizontal direction on the substrate and comprising a plurality of bit lines and a plurality of spacer structures, wherein the plurality of bit lines extend in a second horizontal direction intersecting the first horizontal direction, and the plurality of spacer structures are provided on both sidewalls of the plurality of bit lines;
a plurality of direct contacts connecting the plurality of active regions to the plurality of bit lines;
a plurality of pad isolation structures spaced apart from each other in the second horizontal direction with the plurality of direct contacts therebetween, wherein the plurality of pad isolation structures are between the a lower surface of the substrate and the plurality of bit line structures;
a plurality of conductive vertical structures comprising a plurality of conductive expanded pads and a plurality of conductive contact plugs, wherein the plurality of conductive expanded pads are spaced apart from each other in the first horizontal direction with the plurality of pad isolation structures therebetween, and the plurality of conductive contact plugs are in contact with the plurality of conductive expanded pads and extend in a vertical direction; and
a plurality of separation fences arranged in the second horizontal direction, between the plurality of conductive vertical structures, and having side surfaces extending linearly adjacent an interface between the plurality of conductive expanded pads and the plurality of conductive contact plugs.

18. The IC device of claim 17, wherein lower surfaces of the plurality of separation fences are closer to the lower surface of the substrate than lower surfaces of the plurality of conductive expanded pads.

19. The IC device of claim 17, wherein each of the plurality of separation fences comprises:
a first portion facing one of the plurality of conductive expanded pads; and
a second portion facing one of the plurality of conductive contact plugs, and
wherein the first portion and the second portion are integrated with each other.

20. The IC device of claim 17, wherein a central axis of each of the plurality of separation fences is perpendicular to the substrate.
